(19) United States
(12) Patent Application Publication
(10) Pub. No.: US 2024/0356491 A1
(43) Pub. Date: Oct. 24, 2024

(54) AMPLIFIER AND METHOD FOR CONTROLLING THE SAME

(71) Applicant: REALTEK SEMICONDUCTOR CORPORATION, HSINCHU (TW)

(72) Inventor: SHIH-HSIUNG HUANG, HSINCHU COUNTY (TW)

(21) Appl. No.: 18/629,516

(22) Filed: Apr. 8, 2024

(30) Foreign Application Priority Data
Apr. 21, 2023 (TW) 112114978

(51) Int. Cl. H03F 1/02; H03F 3/45

(52) U.S. Cl. CPC H03F 1/0205; H03F 3/45179

(57) ABSTRACT

The present application discloses an amplifier and a method for controlling the same. The amplifier includes a first P-type transistor, a second P-type transistor, a first N-type transistor and a second N-type transistor. At a first amplification stage, an AC component of a second input signal is amplified by the second P-type transistor into a first amplified signal at an output terminal. The first P-type transistor then amplifies an AC component of a first input signal into a second amplified signal. The second amplified signal is superposed on the first amplified signal at the output terminal.

### CROSS-REFERENCE TO RELATED APPLICATIONS

This application claims priority of Taiwan application No. 112114978 filed on Apr. 21, 2023, which is incorporated by reference in its entirety.

### TECHNICAL FIELD

The present application relates to a circuit; in particular, to an amplifier and a method for controlling the same.

### BACKGROUND

With the advancement of the manufacturing processes, the operating voltage is getting lower and lower. Therefore, how to solve the limitation of output swing while at the same time increasing the gain has become one of the urgent issues to be solved in the related field.

### SUMMARY OF THE INVENTION

The present application provides an amplifier, including: a first P-type transistor, wherein a gate of the first P-type transistor is coupled to a first input signal, and a source of the first P-type transistor is coupled to a first node; a second P-type transistor, wherein a gate of the second P-type transistor is coupled to a second input signal, a source of the second P-type transistor is coupled to a drain of the first P-type transistor, and a drain of the second P-type transistor is coupled to an output terminal; a first N-type transistor, wherein a gate of the first N-type transistor is coupled to a third input signal, and a source of the first N-type transistor is coupled to a second node; a second N-type transistor, wherein a gate of the second N-type transistor is coupled to a fourth input signal, a source of the second N-type transistor is coupled to the drain of the first N-type transistor, and the drain of the second N-type transistor is coupled to the output terminal; a first capacitor, selectively coupled between a first reference voltage and a second reference voltage or between the first node and the second node; a second capacitor, selectively coupled between a third reference voltage and a fourth reference voltage or between the source of the second P-type transistor and the source of the second N-type transistor; wherein in a first amplification stage, the second P-type transistor amplifies an AC component of the second input signal into a first amplified signal at the output terminal; and then in a second amplification stage, the first P-type transistor amplifies an AC component of the first input signal into a second amplified signal, and the second amplified signal is superimposed on the first amplified signal at the output terminal.

The present application provides method for controlling an amplifier, wherein the amplifier includes: a first P-type transistor, wherein a gate of the first P-type transistor is coupled to a first input signal, and a source of the first P-type transistor is coupled to a first node; a second P-type transistor, wherein a gate of the second P-type transistor is coupled to a second input signal, a source of the second P-type transistor is coupled to a drain of the first P-type transistor, and a drain of the second P-type transistor is coupled to an output terminal; a first N-type transistor, wherein a gate of the first N-type transistor is coupled to a third input signal, and a source of the first N-type transistor is coupled to a second node; a second N-type transistor, wherein a gate of the second N-type transistor is coupled to a fourth input signal, a source of the second N-type transistor is coupled to the drain of the first N-type transistor, and the drain of the second N-type transistor is coupled to the output terminal; a first capacitor, selectively coupled between a first reference voltage and a second reference voltage or between the first node and the second node; a second capacitor, selectively coupled between a third reference voltage and a fourth reference voltage or between the source of the second P-type transistor and the source of the second N-type transistor; and the method includes: in a first amplification stage, controlling the first capacitor to couple between the first reference voltage and the second reference voltage, and controlling the second capacitor to couple between the source of the second P-type transistor and the source of the second N-type transistor; and in a second amplification stage, controlling the first capacitor to couple between the first node and the second node, and controlling the drain of the first P-type transistor to not couple to the third reference voltage, and controlling the second capacitor to couple between the third reference voltage and the fourth reference voltage.

The output swing and gain of an amplifier can be increased simultaneously by using the present disclosure.

### BRIEF DESCRIPTION OF THE DRAWINGS

Aspects of the present disclosure are best understood from the following detailed description when read with the accompanying drawings. It is noted that, in accordance with the common practice in the industry, various features are not drawn to scale. In fact, the dimensions of certain features may be arbitrarily increased or reduced for clarity of discussion.

FIG. 1 is a schematic diagram illustrating an amplifier according to certain embodiments of the present disclosure.

FIG. 2 is a schematic diagram illustrating the amplifier according to the present disclosure configured in a first amplification stage.

FIG. 3 is the equivalent circuit of the amplifier according to the present disclosure in a first amplification stage.

FIG. 4 is a schematic diagram illustrating the amplifier according to the present disclosure configured in a second amplification stage.

FIG. 5 is the equivalent circuit of the amplifier according to the present disclosure in a second amplification stage.

### DETAILED DESCRIPTION

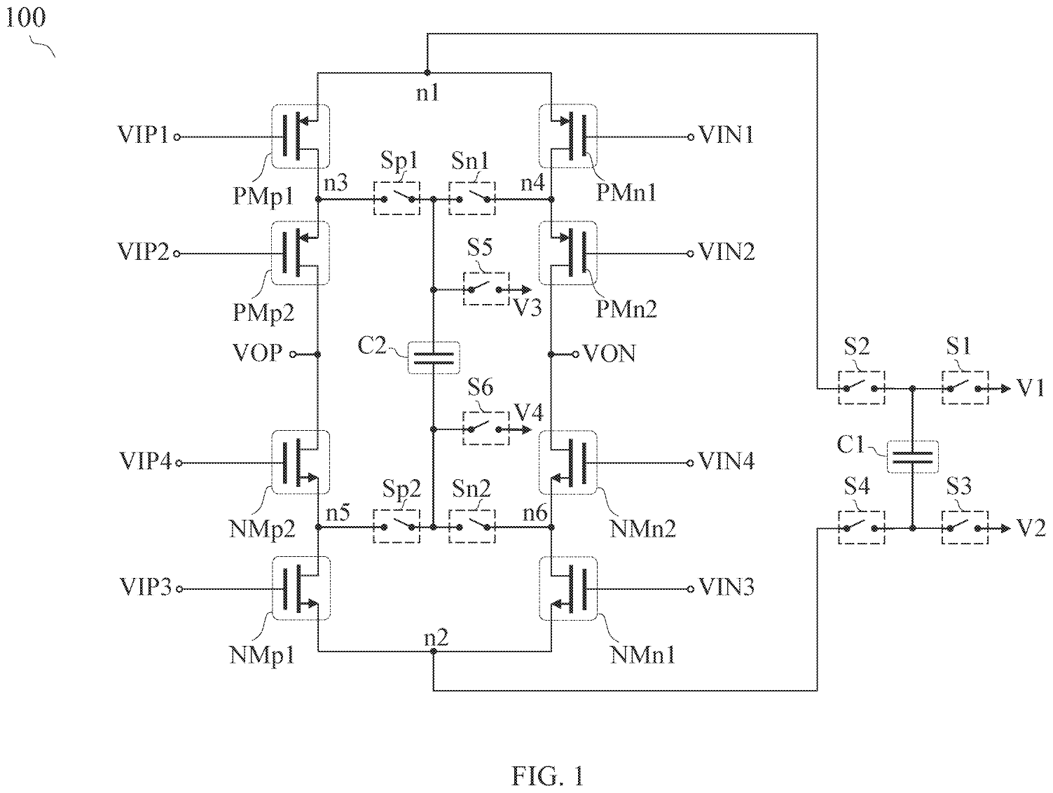

FIG. 1 is a schematic diagram illustrating an amplifier 100 according to certain embodiments of the present disclosure. The amplifier 100 is a cascode amplifier. The common gate amplifier in a general cascode amplifier can increase the output impedance without amplification (gain of 1), but with additional control, the common gate amplifier in the amplifier 100 of the present disclosure can provide a gain greater than 1. Moreover, the amplifier 100 is a dynamic amplifier, meaning that the amplifier 100 does not have a constant current source. The details are described below.

The amplifier 100 includes a differential amplifier body consisting of a first positive terminal P-type transistor PMp1, a second positive terminal P-type transistor PMp2, a first negative terminal P-type transistor PMn1, a second negative terminal P-type transistor PMn2, a first positive terminal N-type transistor NMp1, a second positive terminal N-type transistor NMp2, a first negative terminal N-type transistor NMn1 and a second negative terminal N-type transistor NMn2, which are connected as shown in FIG. 1. Specifically, a node n1 is coupled to the source of the transistor PMp1 and the source of transistor PMn1, wherein the transistor PMp1, the transistor PMp2, the transistor NMp2 and the transistor NMp1 are stacked sequentially and receive an input signal VIP1, an input signal VIP2, an input signal VIP4 and an input signal VIP3 correspondingly from their respective gate; the transistor PMn1, the transistor PMn2, the transistor NMn2 and the transistor NMn1 are stacked sequentially and receive an input signal VIN1, an input signal VIN2, an input signal VIN4 and an input signal VIN3 correspondingly from their respective gate; the node n2 is coupled to the source of transistor NMp1 and the source of transistor NMn1. For ease of illustration, the present disclosure further defines nodes n3, n4, n5 and n6, wherein the nodes n3, n4, n5 and n6 are correspondingly coupled to the drains of the transistor PMp1, the transistor PMn1, the transistor NMp1 and the transistor NMn1, and the nodes n3, n4, n5 and n6 are also correspondingly coupled to the sources of the transistor PMp2, the transistor PMn2, the transistor NMp2 and the transistor NMn2.

Moreover, the amplifier 100 further includes capacitors C1 and C2, configured to dynamically supply a current to the amplifier 100. Switches S1, S2, S3 and S4 are configured to control the capacitor C1 to be selectively coupled between a reference voltage V1 and a reference voltage V2 or between the node n1 and the node n2; switches S5, S6, Sp1, Sp2, Sn1 and Sn2 are configured to control the capacitor C1 to be selectively coupled between the reference voltage V3 and the reference voltage V3 or between nodes n3 and n5 and nodes n4 and n6.

In the present embodiment, the reference voltage V1 is higher than the reference voltage V2, and the reference voltage V3 is higher than the reference voltage V4. The input signal VIP1 and VIN1 are a differential signal pair, with a common mode DC voltage DC1; the input signal VIP2 and VIN2 are a differential signal pair, with a common mode DC voltage DC2; the input signal VIP3 and VIN3 are a differential signal pair, with a common mode DC voltage DC3; the input signal VIP4 and VIN4 are a differential signal pair, with a common mode DC voltage DC4. The AC components vin+ of the input signals VIP1-VIP4 are the same, the AC components vin− of the input signals VIN1-VIN4 are the same; common mode DC voltages DC1-DC4 can vary as needed.

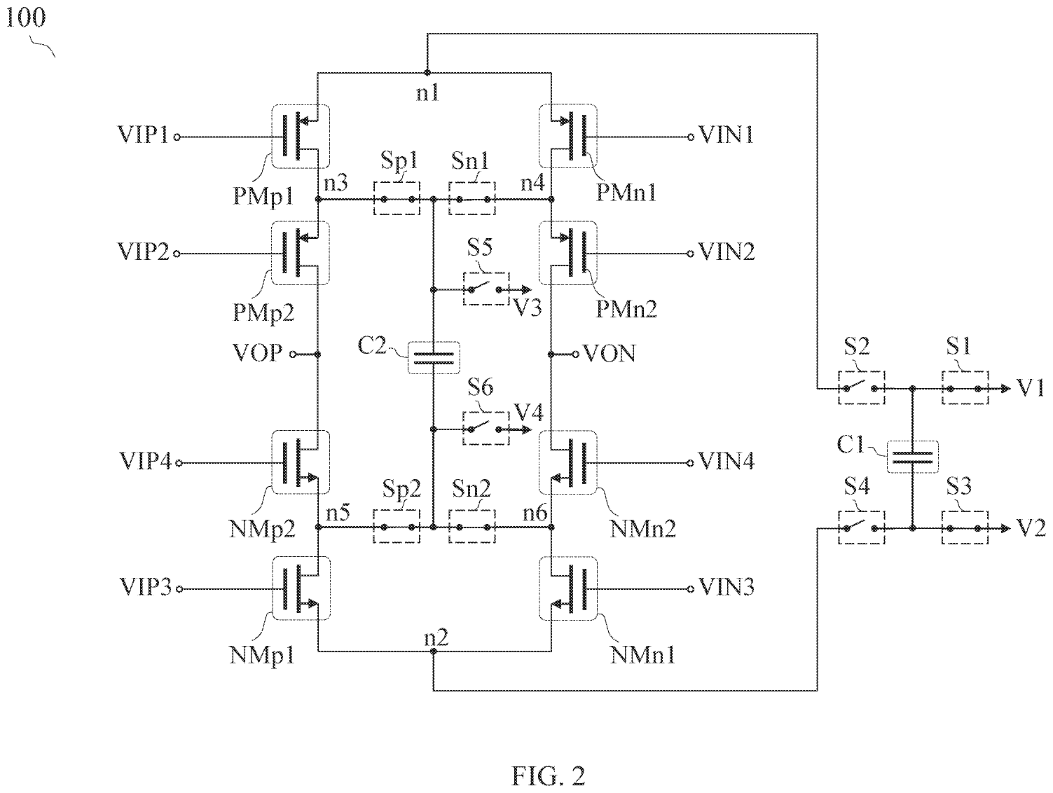

The method for controlling the amplifier 100 can be broadly viewed as having two amplification stages, including a first amplification stage and a second amplification stage; specifically the amplification stage and the amplification stage can be continuously repeated, for example, by simply controlling the switch of the amplifier 100 with a clock signal. In the present embodiment, the configuration of the first amplification stage of the amplifier 100 is shown for example in FIG. 2, in which the switches S2 and S4 are controlled to be disconnected and the switches S1 and S3 to controlled to be connected, so that the first terminal of capacitor C1 is reset to the reference voltage V1 and the second terminal of capacitor C1 is reset to the reference voltage V2. In addition, the switches Sp1, Sn1, Sp2 and Sn2 are controlled to be all conducted so that the first terminal of the capacitor C2 is connected to nodes n3 and n4, and the second terminal of the capacitor C2 is connected to nodes n5 and n6; and the switches S5 and S6 are controlled to be disconnected.

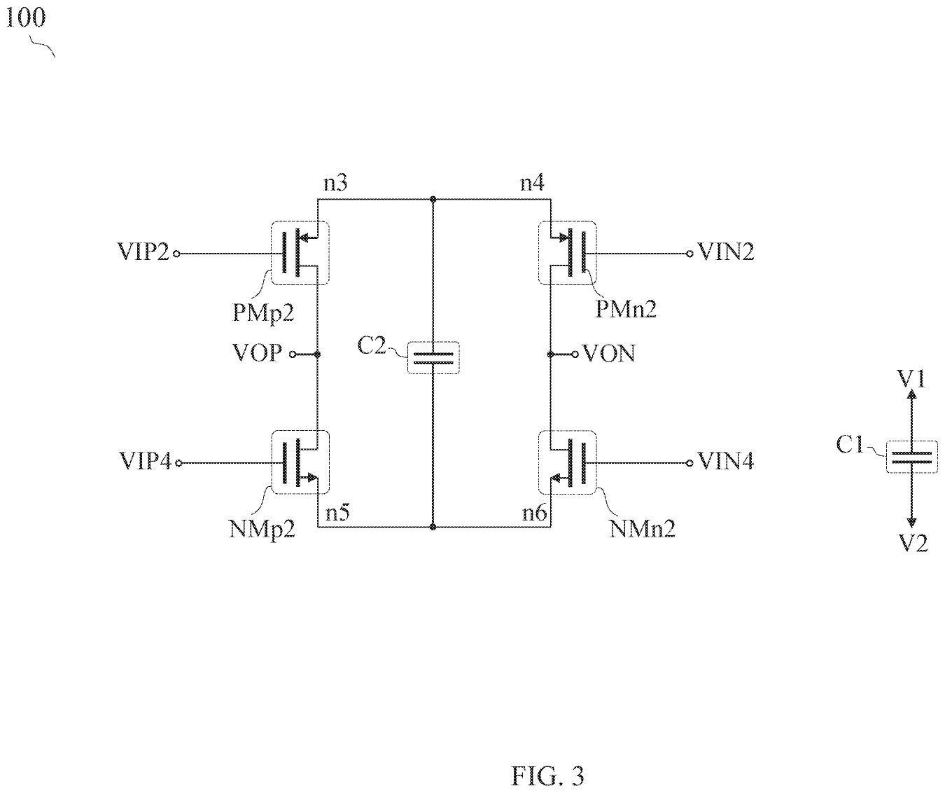

FIG. 3 shows an equivalent circuit of the amplifier according to embodiments of the present disclosure in the first amplification stage. In the case where the first amplification stage and the second amplification stage are cyclic, the first terminal of the capacitor C2 should have been reset to the reference voltage V3 and the second terminal of the capacitor C2 should have been reset to the reference voltage V4 by the time the method proceeds to the first amplification stage, so the initial voltage at nodes n3 and n4 is V3 and the initial voltage at nodes n5 and n6 is V4. The transistors PMp2, PMn2, NMp2, and NMn2 are not in the cutoff region and together form a common source dynamic amplifier. The transistor PMp2 amplifies the AC component vin+ in the input signal VIP2 and generates an amplified signal vin1+ to the output VOP. The transistor NMp2 amplifies the AC component vin+ in the input signal VIP4 and generates an amplified signal vin2+ to the output VOP where the amplified signal vin2+ is superimposes on the amplified signal vin1+. The transistor PMn2 amplifies the AC component vin− in the input signal VIN2 and generates the amplified signal vin1− to the output terminal VON, and the transistor NMn2 amplifies the AC component vin− in the input signal VIN4 and generates the amplified signal vin2− to the output terminal VON, where the amplified signal vin2− is superimposed on the amplified signal vin1−. During the first amplification stage, the charge continues to flow from the first terminal of the capacitor C2 through transistors PMp2 and NMp2 to the second terminal of the capacitor C2; and from the first terminal of the capacitor C2 through transistors PMn2 and NMn2 to the second terminal of the capacitor C2, so that the voltage at nodes n3 and n4 decrease from V3 (so that the source-gate voltage of transistors PMp2 and PMn2 decrease gradually) and the voltage at nodes n5 and n6 increase from V4 (so that the gate-source voltage of transistors NMp2 and NMn2 decrease gradually). In the present embodiment, the amplifier 100 is controlled to enter the second amplification stage when the transistors PMp2, PMn2, NMp2, and NMn2 are close to the cutoff region.

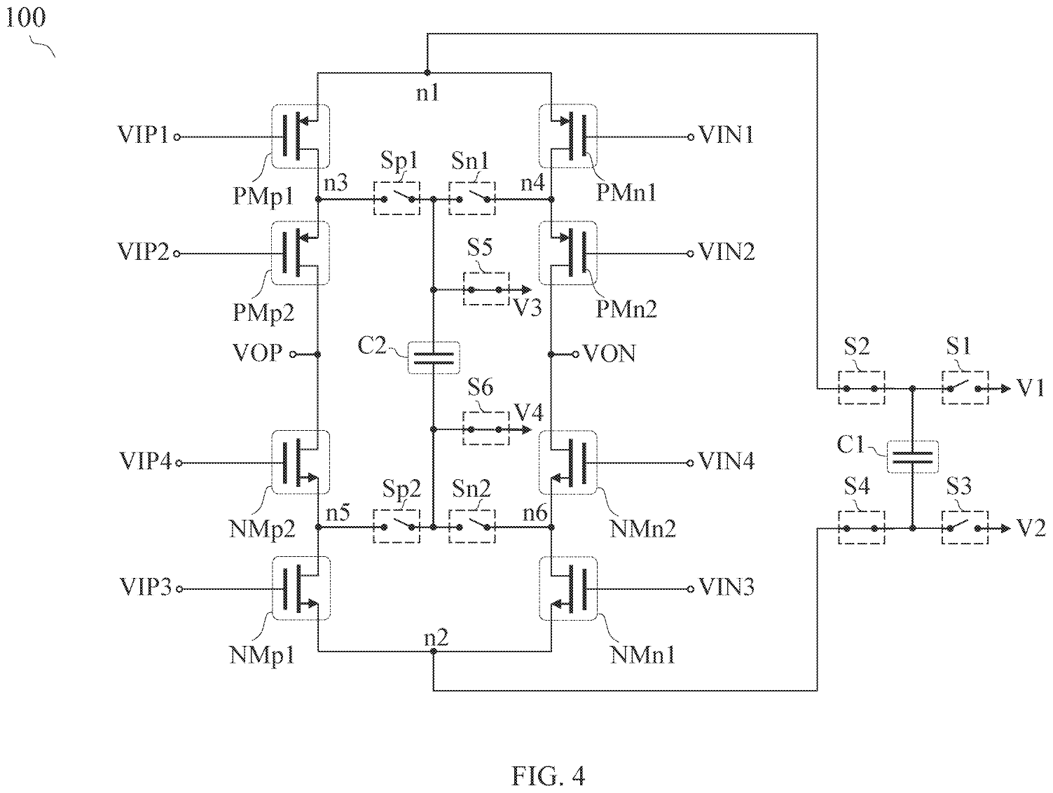

In the present embodiment, the configuration of the amplifier 100 in the second amplification stage is shown in FIG. 4, in which the switches S1, S3 are controlled to be disconnected and the switches S2, S4 are controlled to be conducted, so that first terminal of the capacitor C1 is coupled to the node n1, and the second terminal of the capacitor C1 is coupled to the node n2. Moreover, the switches Sp1, Sn1, Sp2 and Sn2 are all controlled to be disconnected, and the switches S5, S6 are controlled to be conducted, so that the first terminal of the capacitor C2 is reset to the reference voltage V3, and the second terminal of the capacitor C2 is reset to the reference voltage V4.

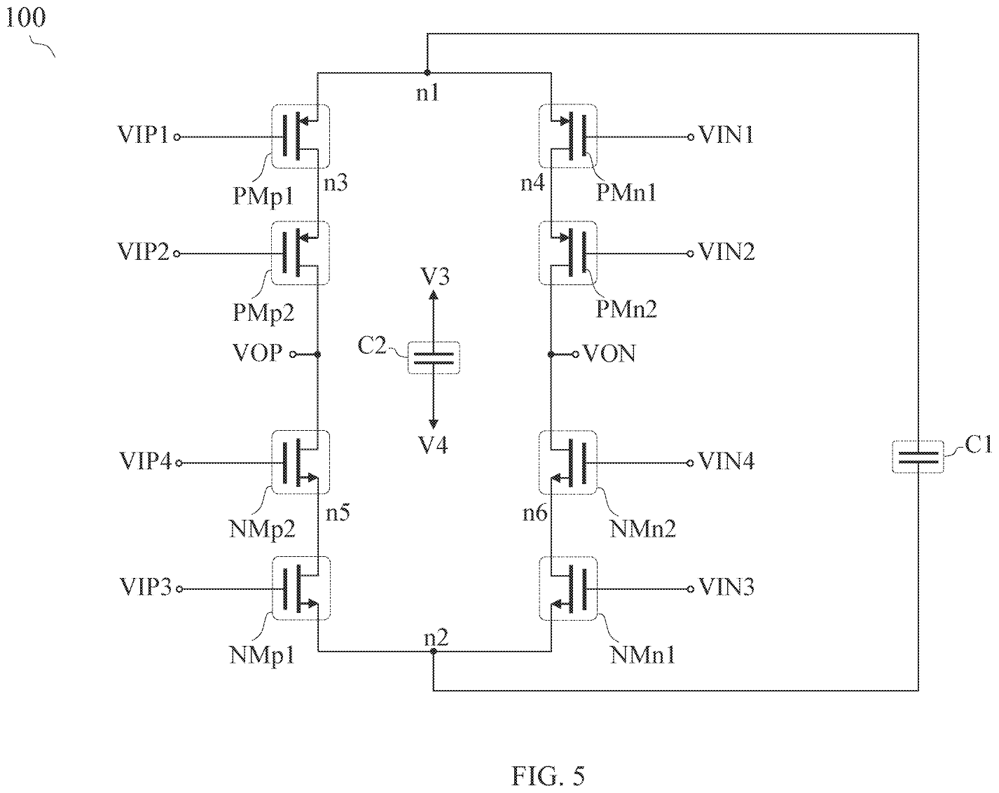

FIG. 5 shows the equivalent circuit of the amplifier 100 operated in the second amplification stage. All of the transistors PMp1, PMp2, PMn1, PMn2, NMp1, NMp2, NMn1 and NMn2 are not in the cutoff region and together form a dynamic cascode amplifier. In this case, the transistors PMp1, PMn1, NMp1 and NMn1 serve as a common source amplifier, whereas the transistors PMp2, PMn2, NMp2 and NMn2 serve as a common gate amplifier. Specifically, the transistor PMp1 amplifies the AC component vin+ in the input signal VIP1 and generates an amplified signal vin3+ to the output terminal VOP, where the amplified signal vin3+ is superimposed on the amplified signals vin1+ and vin2+ generated at the first amplification stage. The transistor NMp1 amplifies the AC component vin+ in the input signal VIP3 and generates an amplified signal vin4+ to the output terminal VOP, where the amplified signal vin4+ is superimposed on the amplified signals vin1+, vin2+ and vin3+.

Similarly, the transistor PMn1 amplifies the AC component vin− in the input signal VIN1 and generates an amplified signal vin3− to the output terminal VON, where the amplified signal vin3− is superimposed on the amplified signals vin1− and vin2− generated in the first amplification stage. The transistor NMn1 amplifies the AC component vin− in the input signal VIN3 and generates an amplified signal vin4− to the output terminal VON, where the amplified signal vin4− is superimposed on amplified signals vin1−, vin2− and vin3−.

It should be noted that in the second amplification stage, although the transistors PMp2, PMn2, NMp2, NMn2 are close to the cutoff region, smaller current can still pass through these transistors. Therefore, in the second amplification stage, the charges can continue to pass, sequentially, through the first terminal of the capacitor C1, then the transistors PMp1, PMp2, NMp2 and NMp1 into the second terminal of the capacitor C1, and through the first terminal of the capacitor C1, then the transistors PMn1, PMn2, NMn2 and NMn1 into the second terminal of the capacitor C1. In this way, the voltage of the node n1 decreases from V1 (so that the source-gate voltages of the transistors PMp1 and PMn1 decrease gradually), and the voltage of the node n2 increases from V2 (so that the gate-source voltages of the transistors NMp1 and NMn1 decrease gradually). In the present embodiment, when the transistors PMp1, PMn1, NMp1 and NMn1 are close to the cutoff region, the amplifier 100 is controlled to return to the first amplification stage.

Moreover, before entering the first amplification stage, nodes n1, n2, n3, n4, n5, n6, and the output terminals VOP and VON of should be reset so as to clear the residual results from the previous cycle.

In certain embodiments, the gates of the transistors PMp1, PMn1, NMp1 and NMn1 may be coupled to a specific reference voltage in the first amplification stage, to ensure that the transistors PMp1, PMn1, NMp1 and NMn1 stay in the cutoff region.

In certain embodiments, the gates of the transistors PMp2, PMn2, NMp2 and NMn2 may be coupled to a specific reference voltage in the second amplification stage, to ensure that the transistors PMp2, PMn2, NMp2 and NMn2 do not enter the cutoff region completely to avoid overly limiting the amount of current that can flow through them.

The amplifier 100 in the present embodiment is a differential amplifier, but the operation of the amplifier 100 can also be applied to a single-ended amplifier, for example, the transistor PMn1, the transistor PMn2, the transistor NMn2 and the transistor NMn1, and switches Sn1 and Sn2 can be removed from the amplifier 100 to obtain a single-ended amplifier architecture.

In general, the amplifier 100 of the present disclosure is a dynamic amplifier and therefore allows for a larger output swing, and the common gate amplifier (transistors PMp2, PMn2, NMp2, and NMn2), which does not provide additional gain under the conventional cascode amplifier architecture, can now be configured as a common source amplifier for amplification in the first amplification stage, and then in the second amplification stage, transistors PMp1, PMn1, NMp1, and NMn1 further continue the amplification, so that the gain can be further increased while retaining the benefits of the cascode amplifier.

What is claimed is:

1. An amplifier, comprising:
a first P-type transistor, wherein a gate of the first P-type transistor is coupled to a first input signal, and a source of the first P-type transistor is coupled to a first node;
a second P-type transistor, wherein a gate of the second P-type transistor is coupled to a second input signal, a source of the second P-type transistor is coupled to a drain of the first P-type transistor, and a drain of the second P-type transistor is coupled to an output terminal;
a first N-type transistor, wherein a gate of the first N-type transistor is coupled to a third input signal, and a source of the first N-type transistor is coupled to a second node;
a second N-type transistor, wherein a gate of the second N-type transistor is coupled to a fourth input signal, a source of the second N-type transistor is coupled to the drain of the first N-type transistor, and the drain of the second N-type transistor is coupled to the output terminal;
a first capacitor, selectively coupled between a first reference voltage and a second reference voltage or between the first node and the second node;
a second capacitor, selectively coupled between a third reference voltage and a fourth reference voltage or between the source of the second P-type transistor and the source of the second N-type transistor;
wherein in a first amplification stage, the second P-type transistor amplifies an AC component of the second input signal into a first amplified signal at the output terminal; and then in a second amplification stage, the first P-type transistor amplifies an AC component of the first input signal into a second amplified signal, and the second amplified signal is superimposed on the first amplified signal at the output terminal.

2. The amplifier of claim 1, wherein in the first amplification stage, the second N-type transistor amplifies an AC component of the fourth input signal into a third amplified signal, and the third amplified signal is superimposed on the first amplified signal at the output terminal, and then in the second amplification stage, the first N-type transistor amplifies an AC component of the third input signal into a fourth amplified signal, and the fourth amplified signal is superimposed on the first amplified signal, the second amplified signal and the third amplified signal at the output terminal.

3. The amplifier of claim 2, wherein in the first amplification stage, the second P-type transistor and the second N-type transistor are not in the cutoff region.

4. The amplifier of claim 3, wherein in the first amplification stage, charge flows from a first terminal of the second capacitor through the second P-type transistor and the second N-type transistor into a second terminal of the second capacitor.

5. The amplifier of claim 4, wherein in the first amplification stage, a source-gate voltage of the second P-type transistor gradually decreases; and a gate-source voltage of the first N-type transistor gradually decreases.

6. The amplifier of claim 5, wherein in the second amplification stage, the first P-type transistor and the first N-type transistor are not in the cutoff region, and the second P-type transistor and the second N-type transistor are not in the cutoff region, either.

7. The amplifier of claim 6, wherein in the second amplification stage, charge flows from the first terminal of the first capacitor through the first P-type transistor, the second P-type transistor, the second N-type transistor and the first N-type transistor into the second terminal of the first capacitor.

8. The amplifier of claim 1, wherein the first reference voltage is higher than the second reference voltage, and the third reference voltage is higher than the fourth reference voltage.

9. The amplifier of claim 1, wherein the AC components of the first input signal, the second input signal, the third input signal and the fourth input signal are the same.

10. The amplifier of claim 9, wherein DC components of the first input signal, the second input signal, the third input signal and the fourth input signal are different.

11. A method for controlling an amplifier, wherein the amplifier comprises:
a first P-type transistor, wherein a gate of the first P-type transistor is coupled to a first input signal, and a source of the first P-type transistor is coupled to a first node;
a second P-type transistor, wherein a gate of the second P-type transistor is coupled to a second input signal, a source of the second P-type transistor is coupled to a drain of the first P-type transistor, and a drain of the second P-type transistor is coupled to an output terminal;
a first N-type transistor, wherein a gate of the first N-type transistor is coupled to a third input signal, and a source of the first N-type transistor is coupled to a second node;
a second N-type transistor, wherein a gate of the second N-type transistor is coupled to a fourth input signal, a source of the second N-type transistor is coupled to the drain of the first N-type transistor, and the drain of the second N-type transistor is coupled to the output terminal;
a first capacitor, selectively coupled between a first reference voltage and a second reference voltage or between the first node and the second node;
a second capacitor, selectively coupled between a third reference voltage and a fourth reference voltage or between the source of the second P-type transistor and the source of the second N-type transistor; and
the method comprises:
in a first amplification stage, controlling the first capacitor to couple between the first reference voltage and the second reference voltage, and controlling the second capacitor to couple between the source of the second P-type transistor and the source of the second N-type transistor; and
in a second amplification stage, controlling the first capacitor to couple between the first node and the second node, and controlling the drain of the first P-type transistor to not couple to the third reference voltage, and controlling the second capacitor to couple between the third reference voltage and the fourth reference voltage.

12. The method according to claim 11, wherein the step of controlling the first capacitor to couple between the first reference voltage and the second reference voltage comprises:
controlling the first capacitor to couple between the first reference voltage and the second reference voltage, so that a voltage of a first terminal of the first capacitor equals to the first reference voltage, and so that a voltage of a second terminal of the first capacitor equals to the second reference voltage.

13. The method according to claim 12, wherein the step of controlling the second capacitor to couple between the third reference voltage and the fourth reference voltage comprises:
controlling the second capacitor to couple between the third reference voltage and the fourth reference voltage, so that the voltage of the first terminal of the second capacitor equals to the third reference voltage, and so that the voltage of the second terminal of the second capacitor equals to the fourth reference voltage.

14. The method according to claim 13, wherein the step of controlling the second capacitor to couple between the source of the second P-type transistor and the source of the second N-type transistor comprises:
controlling the second capacitor to couple between the source of the second P-type transistor and the source of the second N-type transistor, so that charge flows from the first terminal of the second capacitor through the second P-type transistor and the second N-type transistor into the second terminal of the second capacitor.

15. The method according to claim 14, wherein the step of controlling the first capacitor to couple between the first node and the second node comprises:
controlling the first capacitor to couple between the first node and the second node, so that charge flows from the first terminal of the first capacitor through the first P-type transistor, the second P-type transistor, the second N-type transistor and the first N-type transistor into the second terminal of the first capacitor.

16. The method according to claim 15, wherein in the first amplification stage, the second P-type transistor and the second N-type transistor are not in cutoff region.

17. The method according to claim 16, wherein in the first amplification stage, a source-gate voltage of the second P-type transistor gradually decreases; and a gate-source voltage of the second N-type transistor gradually decreases.

18. The method according to claim 17, wherein when the first P-type transistor and the first N-type transistor are not in a cutoff region, and the second P-type transistor and the second N-type transistor are not in the cutoff region, wither.

19. The method according to claim 11, wherein the first reference voltage is higher than the second reference voltage, and the third reference voltage is higher than the fourth reference voltage.

20. The method according to claim 11, wherein the AC components of the first input signal, the second input signal, the third input signal and the fourth input signal are the same.
